(19) United States
(12) Patent Application Publication
(10) Pub. No.: US 2024/0373612 A1
(43) Pub. Date: Nov. 7, 2024

(54) MANAGEMENT DEVICE, MOUNTING SYSTEM, AND PRODUCTION METHOD

(71) Applicant: FUJI CORPORATION, Chiryu (JP)

(72) Inventors: Takamitsu YANO, Anjo-shi (JP); Norimitsu YAMAMURA, Anjo-shi (JP); Isao ANGATA, Toyokawa-shi (JP)

(73) Assignee: FUJI CORPORATION, Chiryu (JP)

(21) Appl. No.: 18/561,367

(22) PCT Filed: Jun. 23, 2021
(86) PCT No.: PCT/JP2021/023752

§ 371 Date: Nov. 16, 2023

(51) Int. Cl. H05K 13/08

(52) U.S. Cl. CPC H05K 13/086; H05K 13/0882

(57) ABSTRACT

A management device for a mounting system that distributes, to an automatic machine that is a mounting device in which supply members are automatically exchanged by a movable work device, the supply members to be installed on the automatic machine with an individual setup for installing the supply members at individual positions set in each production of multiple types of the process target objects; distributes, to a manual machine that is a mounting device in which supply members are exchanged by an operator, the supply members to be installed on the manual machine with a common setup for installing the supply members holding a common component at a common position set in the production of the multiple types of the process target objects; and creates production plan information including a production job for each of the multiple types of the process target objects.

### TECHNICAL FIELD

The present description discloses a management device, a mounting system, and a production method.

### BACKGROUND ART

Conventionally, as a mounting system, there has been proposed a mounting system that classifies a component into a common component and a non-common component based on a level of a degree of commonality of a component used between boards of respective types, fixedly gives an arrangement position to the common component to be the same position through an installation operation of boards of all types, allocates the non-common component to a non-priority arrangement position of a component supply section, individually gives an arrangement position to the non-common component to be a position corresponding to each board of each type, and determines a component arrangement position (for example, refer to Patent Document 1). In the mounting system, it is possible to improve the production efficiency of a mounter of small quantity batch production. In addition, as a mounting system, there has been proposed a mounting system including a mounting device in which feeders holding components are automatically exchanged by a movable work device (for example, see Patent Literature 2).

### PATENT LITERATURE

Patent Literature 1: JP2009-107197A
Patent Literature 2: WO 2018/179147

### SUMMARY OF THE INVENTION

### Technical Problem

Here, the mounting system may be a production line including a mounting device in which feeders holding components are automatically exchanged and a mounting device in which the feeders are manually exchanged by an operator. However, in the mounting system described above, such a configuration has not been studied. In such a mounting system, it has been required to achieve higher efficiency.

A main object of the present disclosure is to provide a management device, a mounting system, and a production method capable of achieving higher efficiency in a mounting system including an automatic machine in which members are automatically exchanged and a manual machine in which members are manually exchanged.

The present disclosure employs the following means in order to achieve the main object described above.

A management device of the present disclosure is a management device for use in a mounting system including a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section, one or more automatic machines that are the mounting devices in which the supply members are automatically exchangeable by the movable work device, and one or more manual machines that are the mounting devices in which the supply members are manually exchanged, the management device including a control section configured to distribute, to the automatic machine, the supply members to be installed on the automatic machine with a tendency that an individual setup for installing the supply members at individual positions is mainly set in each production of multiple types of the process target objects, distribute, to the manual machine, the supply members to be installed on the manual machine with a tendency that a common setup for installing the supply members holding a common component at a common position is mainly set in the production of the multiple types of the process target objects, and create production plan information including a production job for each of the multiple types of the process target objects.

In the management device, in the manual machine of the mounting device in which the supply members are manually exchanged, it is possible to further reduce a frequency of a setup change when the production of various process target objects is switched, by mainly setting the common setup. Further, in the management device, in the automatic machine of the mounting device in which the supply members are automatically exchanged, it is possible to set each of the production jobs in which the mounting process can be executed at a higher speed, by mainly setting the individual setup. Accordingly, in the management device, it is possible to create the production plan information in consideration of the circumstances of the automatic machine and the manual machine, and it is possible to achieve higher efficiency in the production of the process target object. Here, the “tendency that the individual setup is mainly set” refers to, for example, a tendency that partial inclusion of a setup other than the individual setup is allowed and the individual setup is mainly set as a whole. In addition, the “tendency that common setup is mainly set” refers to, for example, a tendency that partial inclusion of a setup other than the common setup is allowed and the common setup is mainly set as a whole.

### BRIEF DESCRIPTION OF DRAWINGS

FIG. 1 is a schematic diagram illustrating an example of mounting system 10.

FIG. 2 is a diagram schematically illustrating configurations of mounting device 15 and loader 18.

FIG. 3 is a diagram illustrating an example of information stored in storage section 63.

FIG. 4 is a flowchart illustrating an example of a production plan information creation processing routine.

FIG. 5 is a diagram illustrating an example of processing of distributing supply members in a shortest mode.

FIG. 6 is a diagram illustrating an example of processing of distributing the supply members in an optimum mode.

FIG. 7 is a diagram illustrating an example of another production plan information 64B.

FIG. 8 is a diagram illustrating an example of another production job 65B.

### DESCRIPTION OF EMBODIMENTS

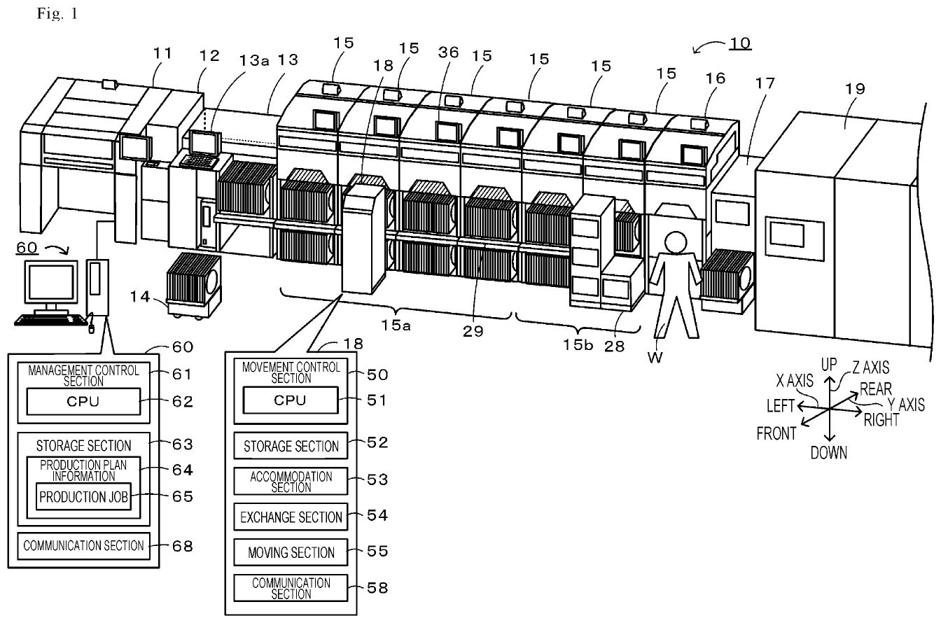

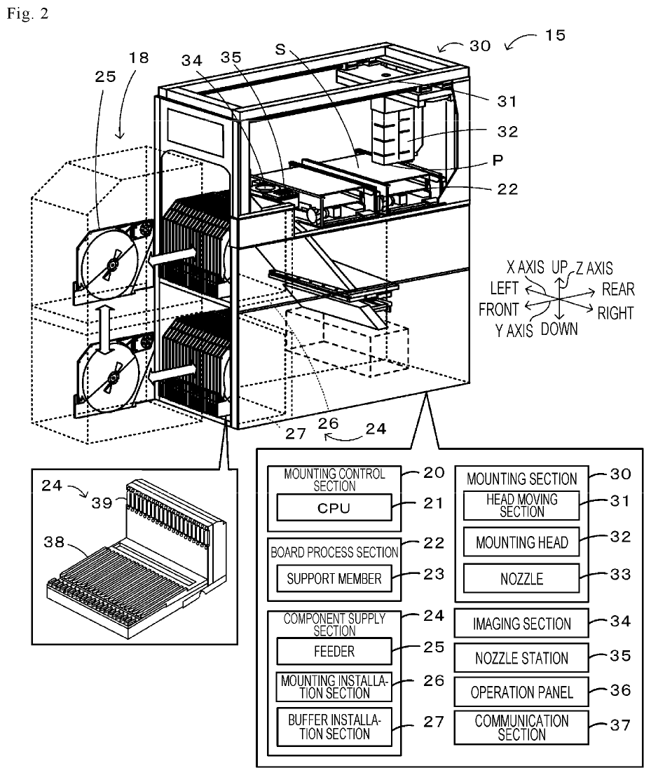

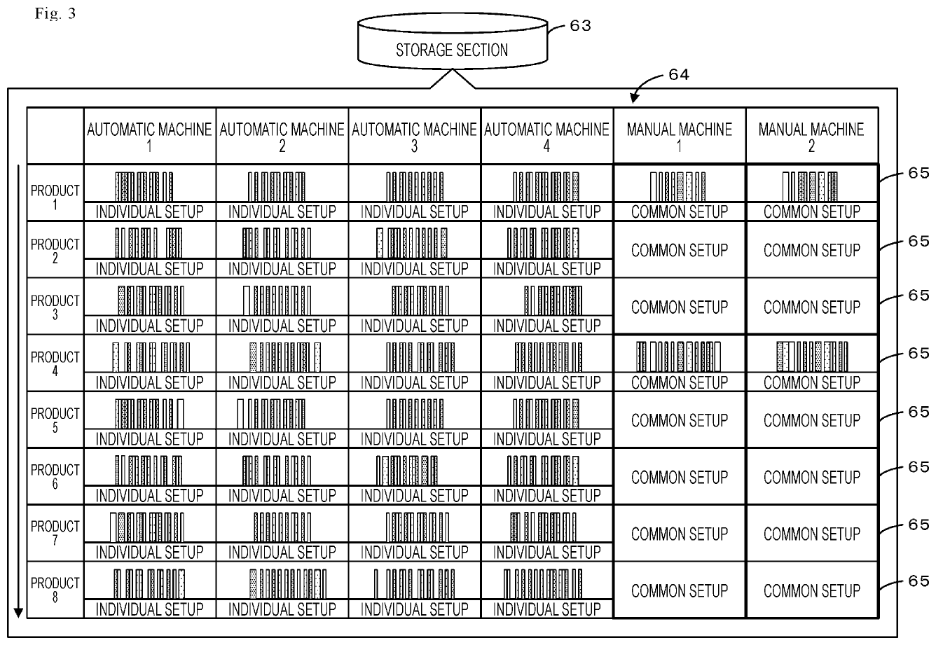

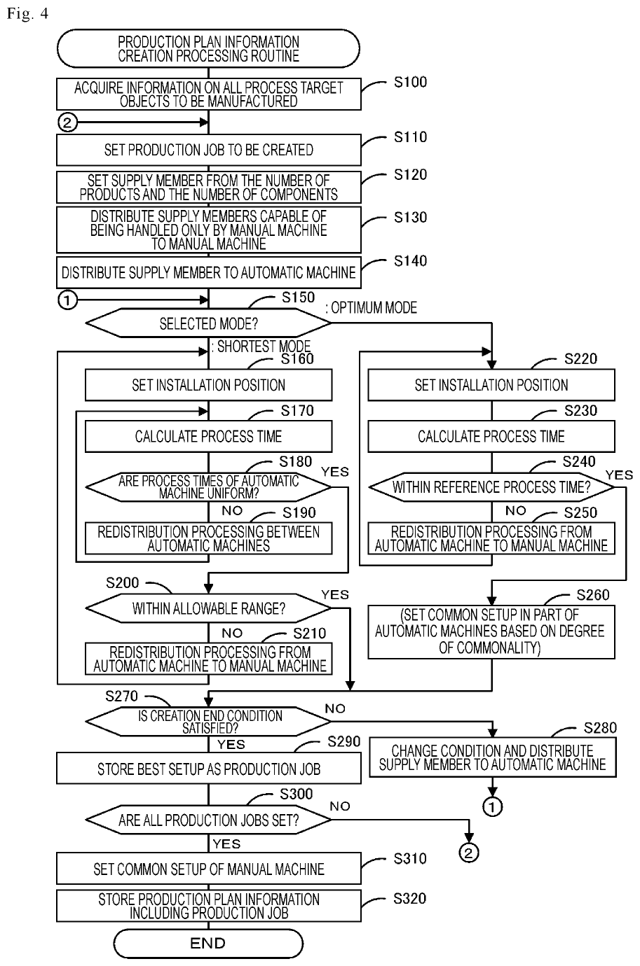

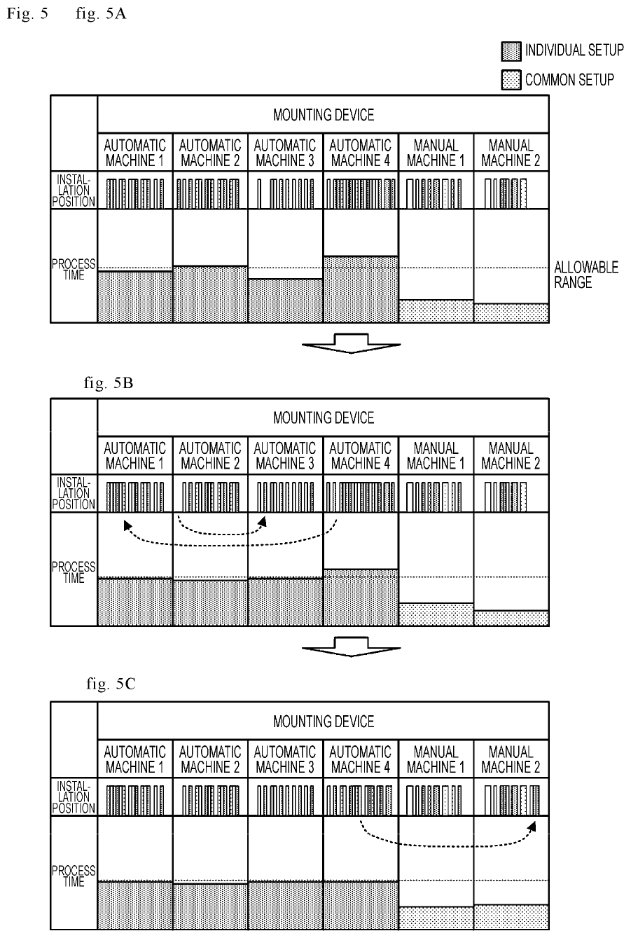

The present embodiment will be described below with reference to drawings. FIG. 1 is a schematic diagram illustrating an example of mounting system 10 of the present disclosure. FIG. 2 is a diagram schematically illustrating configurations of mounting device 15 and loader 18 that is a movable work device. FIG. 3 is a diagram illustrating an example of production plan information 64 and production job 65 stored in storage section 63 of management device 60. In the present embodiment, a left-right direction (X axis), a front-rear direction (Y axis), and an up-down direction (Z axis) are as illustrated in FIGS. 1 and 2.

Mounting system 10 is configured, for example, as a production line in which devices, which execute a mounting process of components P on board S (see FIG. 2) as a process target object, are arranged in a conveyance direction of board S. Here, the process target object will be described as board S, but the process target object is not particularly limited as long as the process target object is an object on which component P is mounted, and may be a substrate having a three-dimensional shape. As illustrated in FIG. 1, mounting system 10 includes printing device 11, printing inspection device 12, storage device 13, storage PC 13a, automatic conveyance vehicle 14, mounting device 15, mounting inspection device 16, conveyance device 17, loader 18, reflow device 19, management device 60, and the like. In mounting system 10, as mounting device 15, one or more automatic machines 15a in which supply members is automatically exchangeable by loader 18 as the movable work device and one or more manual machines 15b in which the supply members are manually exchanged are provided. Here, for convenience of description, mounting system 10 including four automatic machines 15a and two manual machines 15b will be described as an example.

Printing device 11 is a device that prints viscous fluid, such as a solder paste, a conductive paste, or an adhesive, on board S. Printing inspection device 12 is a device that inspects a state of the printed viscous fluid. Storage device 13 is a storage place for storing feeders 25 as the supply members to be used in mounting device 15. Storage device 13 is provided in a front lower part of the conveyance device between printing inspection device 12 and mounting device 15. Storage PC 13a is a device that manages feeders 25 stored in storage device 13. Mounting inspection device 16 is a device that inspects the state or the like of component P mounted on board S. Conveyance device 17 is a device that conveys board S to a downstream device. The supply members or the like to be exchanged by operator W are stored in the front lower part of conveyance device 17. Reflow device 19 is a device that reflows board S on which the viscous fluid is printed and component P is mounted.

As illustrated in FIG. 1, storage device 13 is a device that temporarily stores feeders 25 as the supply members to be used in mounting device 15. Storage device 13 includes a conveyance device that conveys board S and storage PC 13a that manages information, and is provided between printing inspection device 12 and mounting device 15. Storage device 13 includes an installation section similar to component supply section 24 described later. When feeder 25 is connected to the installation section, a controller of feeder 25 outputs information on feeder 25 to storage PC 13a connected to storage device 13. In storage device 13, while feeders 25 are conveyed by automatic conveyance vehicle 14, feeders 25 may be conveyed by operator W.

Automatic conveyance vehicle 14 conveys members to be used in mounting system 10, for example, printing related members to be used in printing device 11, or conveys mounting related members to be used in loader 18. Automatic conveyance vehicle 14 automatically conveys, for example, the printing related members or the mounting related members between a warehouse (not illustrated) and storage device 13. The mounting related members include, for example, feeders 25 as the supply members, support member 23, mounting head 32 as a pickup member, and nozzle 33. Here, the description will be made in which automatic conveyance vehicle 14 mainly conveys feeders 25. Automatic conveyance vehicle 14 may be an automatic guided vehicle (AGV) that moves on a predetermined track, or may be an autonomous mobile robot (AMR) that moves to a destination on a free route by detecting surroundings thereof.

Mounting device 15 is a device that picks up components and mounts the components on board S. Mounting device 15 includes mounting control section 20, board process section 22, component supply section 24, mounting section 30, imaging section 34, nozzle station 35, operation panel 36, communication section 37, and communication section 37. Mounting control section 20 is configured as a microprocessor centered on CPU 21 and controls the entire device, as illustrated in FIG. 2. Mounting control section 20 outputs control signals to board process section 22, component supply section 24, mounting section 30, imaging section 34, and operation panel 36, and inputs signals from board process section 22, component supply section 24, mounting section 30, imaging section 34, and operation panel 36. Mounting control section 20 includes a storage section which stores a production job including information on component P and information on a disposition order in which components P are mounted on board S, a disposition position, installation positions of feeders 25 that pick up component P, or the like. The production job stored in the storage section includes the same information as production job 65 illustrated in FIG. 3.

Board process section 22 executes the series of processes of loading, conveying, fixing at a mounting position, and unloading board S, as well as a process of supporting board S from below using support member 23. Board process section 22 includes a pair of conveyor belts that are provided at intervals in the front-rear direction while being stretched in the left-right direction in FIG. 1. Board S is conveyed by the conveyor belts. Support member 23 includes a backup plate as a base, a backup pin disposed in any position depending on board S, and the like. This backup pin may be configured to be disposed at a predetermined position on the backup plate by mounting section 30.

Component supply section 24 is a unit that supplies component P to mounting section 30. In component supply section 24, feeders 25 as the supply members including a reel wound with a tape as a holding member holding the component is installed on one or more installation sections. As illustrated in FIG. 2, component supply section 24 has two upper and lower installation sections on which feeders 25 can be installed, on a front side of the device. The upper stage is mounting installation section 26 from which the component can be picked up by mounting section 30, and the lower stage is buffer installation section 27 from which the component cannot be picked up by mounting section 30. Here, mounting installation section 26 and buffer installation section 27 are collectively referred to as installation sections. In component supply section 24, multiple slots 38 which are arranged in the X direction at predetermined intervals and into which rail members of feeders 25 are inserted, and connection sections 39 into which connectors provided at distal ends of feeders 25 are inserted are disposed. Feeder 25 includes the controller (not illustrated). The controller stores information, such as ID of the tape in feeder 25, a component type, or a remaining number of components. When feeder 25 is connected to connection section 39, the controller transmits the information on feeder 25 to mounting control section 20.

Component supply section 24 may include tray unit 28 having trays as the supply members on which multiple components P are arranged and placed. For example, manual machine 15b may include tray unit 28. Tray unit 28 is used to supply a large component that cannot be held by the tape. Tray unit 28 includes a tray that holds component P and a moving section that moves the tray up and down and forward and backward, and moves the tray between an accommodation position and a pickup position. Further, component supply section 24 may include a wafer unit that supplies a wafer as component P.

Mounting section 30 is a unit that picks up component P from component supply section 24 and puts the component on board S fixed to board process section 22. Mounting section 30 includes head moving section 31, mounting head 32, and nozzle 33. Head moving section 31 includes a slider moving by being guided by guide rails in the XY directions, and a motor that drives the slider. Mounting head 32 picks up one or more components and is moved in the XY directions by head moving section 31. Mounting head 32 is detachably installed on the slider. One or more nozzles 33 are detachably installed on a lower surface of mounting head 32. Nozzle 33 picks up the component by using a negative pressure. There are multiple types of nozzle 33 adapted for each type or size of component P. There are multiple types of mounting heads 32, and the types and the number of nozzles 33 that can be installed are set for each type. Mounting head 32 is set so that, for example, one or two nozzles 33 can be installed for a large component, and any of 4, 6, 8, 12, and 16 nozzles 33 can be installed for a general-purpose component. Instead of nozzle 33, a pickup member that picks up the component may be a mechanical chuck or the like that mechanically holds the component.

Imaging section 34 is a camera that images an upper side, and images component P or the like held by mounting head 32. Imaging section 34, as illustrated in FIG. 1, is a device that captures images of one or more components P picked up and held by mounting head 32. Imaging section 34 is disposed between component supply section 24 and board process section 22. An imaging range of imaging section 34 is above part camera 17. Imaging section 34 captures one or two or more images when mounting head 32 holding component P passes above imaging section 34, and outputs the captured images to mounting control section 20. Mounting control section 20 can confirm the pickup position, the shape, or the like of component P from the captured images of imaging section 34. Nozzle station 35 is an accommodation section in which various nozzles 33 to be used in mounting section 30 stand by. Operation panel 36 is a unit that receives inputs from operator W and presents information to operator W. Operation panel 36 is disposed on a front surface of mounting device 15, and includes a display section as a display and a touch panel-type operation section including buttons. Communication section 37 is an interface that executes exchange of information with an external device, such as storage PC 13a or management device 60.

Loader 18 is a movable work device and is a device that moves within a movement region in front of mounting system 10 and automatically recovers and replenishes feeders 25 of mounting device 15. Loader 18 includes movement control section 50, storage section 52, accommodation section 53, exchange section 54, moving section 55, and communication section 58. Movement control section 50 is configured as a microprocessor centered on CPU 51 and controls the entire device. Storage section 52 is, for example, HDD or the like that stores various data, such as processing programs, and stores information on an exchange operation. Accommodation section 53 has an accommodation space in which feeders 25 are accommodated. Accommodation section 53 is configured to accommodate, for example, four feeders 25. Exchange section 54 is a mechanism that moves feeder 25 in and out as well as moving feeder 25 in the up-down direction (see FIG. 2). Exchange section 54 has a clamp section that clamps feeder 25, a Y-axis slider that moves the clamp section in the Y-axis direction (front-rear direction), and a Z-axis slider that moves the clamp section in the Z-axis direction (up-down direction). Exchange section 54 executes installation and removal of feeder 25 at mounting installation section 26, and installation and removal of feeder 25 at buffer installation section 27. Moving section 55 is a mechanism that moves loader 18 in the X-axis direction (left-right direction) along X-axis rail 29 disposed on a front surface of mounting device 15. Communication section 58 is an interface that executes exchange of information with an external device, such as storage PC 13a or mounting device 15. Loader 18 outputs a current position and executed operation contents to storage PC 13a. Loader 18 can automatically attach and detach feeders 25 as the supply members, and may also be configured to recover and replenish the mounting related members, the printing related members, or the like.

Management device 60 (see FIG. 1) is configured as a server that manages information on each device of mounting system 10. Management device 60 includes management control section 61 that controls the entire device, storage section 63 that stores various information, and communication section 68 that execute bidirectional communication with an external device, such as mounting system 10, automatic conveyance vehicle 14, and loader 18. Management device 60 creates and manages production plan information 64 used for the mounting process of the component or production job 65 in production plan information 64, and acquires and manages information on mounting system 10.

As illustrated in FIG. 3, production plan information 64 including production job 65 of each board S is stored in storage section 63. Production job 65 is set for each board S as a product to be produced. Production job 65 includes information on the type and the number of components P disposed on specific board S, the installation positions of feeders 25 holding components P, or information on the disposition order and the disposition position of components P mounted on board S. FIG. 3 illustrates an image of the position at which feeder 25 is installed. Mounting device 15 includes an individual setup and a common setup as the installation positions of respective feeders 25. The individual setup is a setup for installing feeders 25 as the supply members at individual positions in each production of board S as multiple types of the process target objects. The common setup is a setup for installing feeders 25 as the supply members holding common component P at a common position in the production of board S as the multiple types of the process target objects. In the individual setup, since feeders 25 can be installed at a unique position in the production of each board S, it is possible to further shorten the time, but it is necessary to remove and install the feeders 25 many times during the setup change for switching the production. On the other hand, in the common setup, since feeders 25 holding same component P are mounted at the same position over the production of multiple boards S, the movement of feeders 25 is not necessary during the setup change, but flexibility of time reduction or the like may be insufficient. In the common setup, feeder 25 not used for the production may remain installed, and flexibility of slot consumption may be insufficient. For example, management device 60 creates production plan information 64 in which feeders 25 are distributed with the tendency that the individual setup in automatic machine 15a in which feeders 25 are automatically exchanged by loader 18 is mainly set and the tendency that the common setup in manual machine 15b in which feeders 25 are manually exchanged by operator W is mainly set. Therefore, production plan information 64 can further reduce the operation amount of operator W in manual machine 15b, and can execute more efficient production in automatic machine 15a. Here, the “tendency that (specific) setup is mainly set” refers to, for example, a tendency that partial inclusion of setup other than the specific setup is allowed and the specific setup is mainly set as a whole.

Next, an operation of mounting system 10 of the present embodiment configured as described above, that is, processing of creating production plan information 64 will be described. FIG. 4 is a flowchart illustrating an example of a production plan information creation processing routine executed by management control section 61 of management device 60. This routine is stored in storage section 63 of management device 60, and is executed based on the input of operator W when a production plan including the production of multiple boards S is created. When this routine is started, first, CPU 62 acquires information on boards S which are all the process target objects manufactured in the current production plan (S100). For example, CPU 62 acquires the type of component P, the number of components, and the like from the data of board S which is the product, and acquires the number of modules or the number of installation sections of automatic machine 15a or manual machine 15b of mounting device 15 from the configuration of mounting system 10. Next, CPU 62 sets production job 65 to be created this time (S110). For example, CPU 62 sets the production jobs of the products to be created in order from product 1 illustrated in FIG. 3.

Next, CPU 62 sets the type or the number of supply members such as feeders 25 or the trays to be used from the number of products of board S, the number of components, the number of installation sections of component supply section 24, and the like in the set product (S120). For components P (large number of components) disposed in excess of a predetermined unit number (for example, 1,000, 10,000, or the like) within a range not exceeding the total number of installation sections, CPU 62 sets multiple feeders 25 corresponding to the predetermined unit number. Next, CPU 62 distributes supply members such as feeders 25 or the trays holding components P capable of being handled only by manual machine 15b to manual machine 15b (S130). In this case, when there are multiple manual machines 15b in mounting system 10, for example, CPU 62 executes processing of distributing feeders 25 to respective manual machines 15b so that the number of components to be processed is equalized. In this way, since the supply members are distributed to manual machine 15b, the minimum supply members are distributed to manual machine 15b. Next, CPU 62 executes processing of distributing the remaining supply members to respective automatic machines 15a so that the number of components to be processed is equalized (S140). When distributing the supply members, CPU 62 may distribute the supply members so that components P that can be picked up by same nozzle 33 as much as possible are installed on the same device. In this way, CPU 62 distributes all the supply members to the respective devices in a temporary state.

Next, CPU 62 determines which mode is selected in the manufacturing of board S (S150). In mounting system 10, a case where there is a shortest mode or an optimum mode will be described as an example. The shortest mode is a mode in which the supply members are distributed so that a process time of each automatic machine 15a is the shortest. The optimum mode is a mode in which supply members are distributed in accordance with the process time (referred to as a reference process time) of the device other than mounting device 15, such as printing device 11, printing inspection device 12, mounting inspection device 16, conveyance device 17, and reflow device 19 provided in mounting system 10. In mounting system 10, since the process is delayed in the device requiring the longest time, the optimum mode is a mode in which the process time in each mounting device 15 is not equalized or made to be the shortest as long as the process time is within the reference process time determined based on the device. Operator W may set the selected mode in advance, or may input the selected mode at this time. Although the shortest mode or the optimum mode is described here, mounting system 10 may have only one of these modes, or may have another mode in addition to or instead of these modes.

In S150, when the selected mode is the shortest mode, CPU 62 executes the processing of distributing the supply members in accordance with the shortest mode (S160 to S210). FIG. 5 is a diagram illustrating an example of the processing of distributing the supply members in the shortest mode, in which FIG. 5A illustrates an initial state, FIG. 5B illustrates redistribution processing in automatic machine 15a, and FIG. 5C illustrates redistribution processing to manual machine 15b. Here, feeder 25 is described as the supply member. In this processing, CPU 62 first sets the installation positions of feeders 25 distributed to each mounting device 15 (S160). CPU 62 sets the installation positions of feeders 25 so that the operation efficiency related to the pickup, the movement, and the disposition by mounting head 32 is improved. In particular, the installation positions of feeders 25 are temporarily set by mainly setting the individual setup in automatic machine 15a, and mainly setting the common setup in manual machine 15b. For example, in mounting device 15, since component P is imaged by imaging section 34 and confirmed after component P is picked up, CPU 62 may set the installation positions of feeders 25 so that feeder 25 having a highest use frequency is installed on the installation section closer to imaging section 34. In addition, CPU 62 may set the installation positions at which feeders 25 having a higher degree of relevance are disposed closer to each other, for example, frequently picked up at the same time by mounting head 32. CPU 62 sets the installation positions of feeders 25 for each mounting device 15 in accordance with the condition described above.

Next, CPU 62 calculates the process time required for each mounting device 15 based on the set installation positions of feeders 25 (S170). For example, CPU 62 calculates the process time for processing a predetermined number of boards (for example, 10 boards) including the moving time of mounting head 32 (FIG. 5A). Next, CPU 62 determines whether the process times of respective automatic machines 15a are uniform (S180). CPU 62 may determine whether each process time is within a predetermined margin (for example, within 10%). When the process times are not uniform, CPU 62 executes processing of redistributing feeders 25 between automatic machines 15a (S190), and executes the processing of S170 and thereafter. That is, CPU 62 repeatedly executes processing of redistributing feeders 25 between automatic machines 15a and calculating the process time in each device until the uniformity of the process times is achieved. For example, CPU 62 may distribute feeders 25 from automatic machine 15a having a long process time to automatic machine 15a having a short process time (FIG. 5B). In addition, as feeders 25 to be redistributed, feeders having a low degree of relevance to another feeder 25 may be selected, for example, different nozzle 33 needs to be used. When such uniformity is achieved, feeders 25 are distributed to each automatic machine 15a to be at the installation position at which the process time required for each automatic machine 15a is shorter.

On the other hand, when it is determined in S180 that the process times of respective automatic machines 15a are uniform (FIG. 5B), CPU 62 determines whether each of the process times of respective automatic machines 15a is within a predetermined allowable range (S200). For example, the allowable range may be empirically determined based on an upper limit value at which it is recognized that a process amount is overloaded when the process time exceeds the allowable range. When any one of the process times of respective automatic machines 15a exceeds the allowable range, CPU 62 determines that the overload number of feeders 25 are distributed to an automatic machine 15a side, and executes the processing of redistributing feeders 25 from automatic machine 15a to a manual machine 15b side (S210). For example, CPU 62 may select feeders 25 satisfying a predetermined distribution condition and distribute selected feeders 25 to the manual machine 15b side. Feeders 25 to be distributed are selected from among the feeders installed on automatic machine 15a having a longer process time (FIG. 5C). The distribution condition may be, for example, a condition for selecting one or more of the supply member holding component P having a higher degree of commonality based on common use in the production of the multiple types of boards S, the supply member holding component P used in fewer numbers than the standard component, and the supply member holding component P larger than the standard component. It is preferable that component P satisfying these conditions are distributed to manual machine 15b. As the degree of commonality, for example, component P used in two productions may be set to “2”, component P used in three productions may be set to “3”, and component P having a higher value may be component P having a high degree of commonality. The “standard component” may be, for example, a general-purpose component or the like that is more frequently used in mounting device 15. After S210, CPU 62 executes the processing of S160 and thereafter. That is, CPU 62 repeatedly executes the processing of distributing feeders 25 to manual machine 15b, setting the installation positions of distributed feeders 25, and calculating the process times of the respective devices until all of the respective process times fall within the predetermined allowable range in S200.

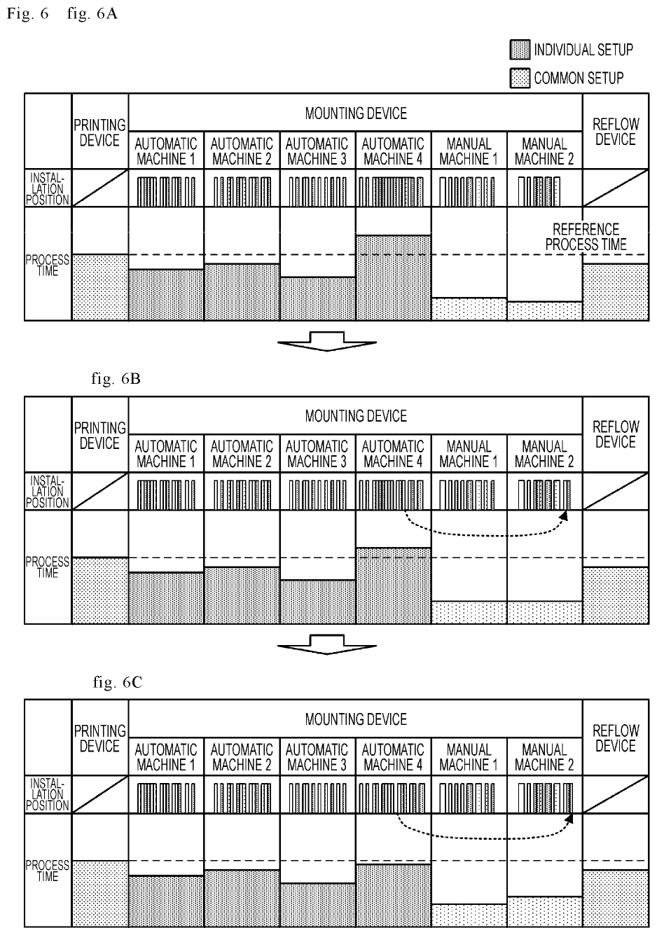

On the other hand, in S150, when the selected mode is the optimum mode, CPU 62 executes the processing of distributing the supply members in accordance with the optimum mode (S220 to S260). FIG. 6 is a diagram illustrating an example of the processing of distributing the supply members in the optimum mode, in which FIG. 6A illustrates an initial state, and FIGS. 6B and 6C illustrate redistribution processing to manual machine 15b. Here, a detailed description of the same processing as that in the shortest mode is omitted, assuming that the same processing as that in the shortest mode is performed. In this processing, CPU 62 first sets the installation positions of feeders 25 distributed to each mounting device 15 (S220). As in the shortest mode, CPU 62 may set the installation positions of feeders 25 so that the operation efficiency by mounting head 32 is improved. CPU 62 temporarily sets the installation positions of feeders 25 by mainly setting the individual setup in automatic machine 15a, and mainly setting the common setup in manual machine 15b. CPU 62 may set the installation positions of feeders 25 so that feeder 25 having a highest use frequency is installed on the installation section closer to imaging section 34. In addition, CPU 62 may set the installation positions at which feeders 25 having a higher degree of relevance are disposed closer to each other, for example, frequently picked up at the same time by mounting head 32. CPU 62 sets the installation positions of feeders 25 for each mounting device 15 in accordance with the condition described above (FIG. 6A).

Next, as in S170, CPU 62 calculates the process time required for each mounting device 15 based on the set installation positions of feeders 25 (S230). Next, CPU 62 determines whether the process time of each of automatic machines 15a is within the predetermined reference process time (S240). The reference process time is a time required for the production process of a predetermined number of boards S, that is, a process time per unit production volume, and the reference process time, which is a threshold value determined based on the process time of another device other than mounting device 15 may be set to a value obtained by adding the predetermined margin to the process time of the device having the longest process time. When all of the process times of respective automatic machines 15a are not within the reference process time, CPU 62 executes the processing of redistributing feeders 25 from automatic machine 15a to the manual machine 15b side in order to reduce the process amount of the device exceeding the reference process time (S250). For example, CPU 62 may select feeders 25 satisfying a predetermined distribution condition among feeders 25 distributed to the device exceeding the reference process time and distribute selected feeder 25 to the manual machine 15b side (FIG. 6B). The distribution condition may be, for example, the condition described in the shortest mode, or may include other conditions in addition to or instead of the condition described above. After S250, CPU 62 executes the processing of S220 and thereafter. That is, CPU 62 repeatedly executes the processing of distributing feeders 25 to manual machine 15b, setting the installation positions of distributed feeders 25, and calculating the process times of the respective devices until all of the respective process times fall within the predetermined reference process time in S240 (FIG. 6C).

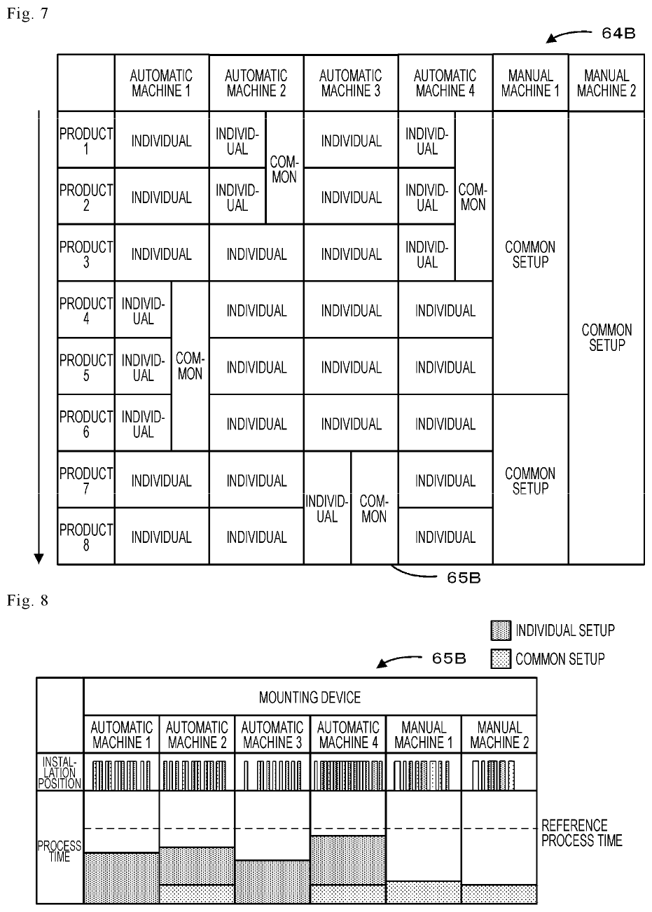

When all of the respective process times are within the predetermined reference process time in S240, CPU 62 may set the common setup to a part of automatic machine 15a in which the individual setup is mainly set based on the degree of commonality of the supply members as necessary (S260). Also in automatic machine 15a, there may be feeder 25 that is commonly used for the production of multiple types of boards S. In S260, processing of setting the installation positions of feeders 25 to the same installation position over the production of multiple types of boards S is executed. When the common setup exists even in a part of automatic machine 15a, it is possible to further reduce the exchange operation of loader 18 in the setup change during the production change. FIG. 7 is a diagram illustrating an example of production plan information 64B in which the common setup is set in a part of the individual setup of automatic machine 15a. FIG. 8 is a diagram illustrating an example of production job 65 B in which the common setup is set in a part of the individual setup of automatic machine 15a. As illustrated in FIG. 7, a part of the individual setup may include the common setup. In addition, in this case, the process time of each automatic machine 15a need only be within the reference process time. Operator W may set in advance whether to execute the processing of S260, or may input whether to set the common setup in a part of the individual setup after the start of this routine. When the processing of S260 is omitted, production plan information 64 in which only the individual setup is installed in automatic machine 15a is obtained (see FIG. 3).

After S260 or when it is determined in S200 that all of the respective process times are within the predetermined allowable range, CPU 62 temporarily saves the current setup and determines whether a creation end condition of production job 65 is satisfied (S270). The creation end condition of production job 65 includes, for example, a case where a setup of a preset number of sets (for example, 500 or 1000) is temporarily saved or a case where a setup is created for a time set in advance (for example, 10 minutes). Here, for example, management device 60 extracts a best setup from a large number of set setups and sets the best setup as production job 65. When the creation end condition of production job 65 is not satisfied, CPU 62 changes the distribution condition of the supply members and distributes the supply members to automatic machine 15a (S280). That is, CPU 62 changes a part or all of the supply members and distributes the supply members to each device. After S280, CPU 62 executes the processing of S150 and thereafter. That is, while changing the installation positions of the supply members, CPU 62 appropriately executes the redistribution between automatic machines 15a or the redistribution from automatic machine 15a to manual machine 15b in accordance with the selected mode, and obtains a large number of setups including which supply member is installed on which installation section.

On the other hand, when the creation end condition is satisfied in S270, CPU 62 extracts the best setup from the large number of temporarily saved setups, and stores the best setup as production job 65 (S290). Subsequently, CPU 62 determines whether all production jobs 65 in the production plan are set (S300), and CPU 62 executes the processing of S110 and thereafter when all production jobs 65 in the production plan are not set. That is, a production job of a product to be created next is set, and the supply members are distributed to automatic machine 15a and manual machine 15b. On the other hand, when all production jobs 65 in the production plan are set in S300, CPU 62 executes processing of setting the common setup of manual machine 15b (S310). CPU 62 sets a common installation position as much as possible in the supply members distributed to manual machine 15b over the production of multiple types of boards S. In addition, when there is a production limit in the common setup, CPU 62 sets a new common setup from the production (see product 4 in FIG. 3 and the like). It is preferable that only one common setup exists in the production plan, but multiple common setup may exist. When the common setup is set for manual machine 15b, it is possible to further reduce the setup change operation of operator W. After S310, CPU 62 stores production plan information 64 including production job 65 in storage section 63 (S320), and this routine ends. As described above, management device 60 can create production plan information 64 in which the features of the operations of both automatic machine 15a and manual machine 15b are added.

Next, a process in which mounting device 15 mounts component P on board S by using production job 65 will be described. First, the mounting process by automatic machine 15a will be described. When the mounting process is started, CPU 21 of mounting control section 20 first acquires production job 65 of the product to be manufactured this time from management device 60. CPU 21 may acquire production job 65 of the host machine for each product from management device 60, or may acquire production plan information 64 including all production jobs 65 of the host machine from management device 60. Loader 18 executes a setup change process of installing each feeder 25 at the installation position set in production job 65. When the production can be started, CPU 21 causes board process section 22 to load and fix board S. Next, based on production job 65, CPU 21 executes processing of causing mounting head 32 to pick up component P from feeder 25 installed on component supply section 24 and putting component P on board S. Mounting head 32 passes above imaging section 34 and causes imaging section 34 to image component P. Based on the captured image, CPU 21 detects, for example, whether a pickup deviation or a shape of component P is normal. When the disposition of component P on board S ends, CPU 21 discharges board S to board process section 22, and repeatedly executes the process described above. During the mounting process, CPU 21 manages the number of consumed components in each feeder 25, and when the remaining number of components is equal to or lower than a warning value, CPU 21 transmits the information to storage PC 13a. Storage PC 13a causes loader 18 to execute the exchange operation of feeders 25 based on an instruction list. Loader 18 moves between storage device 13 and mounting device 15 along X-axis rail 29, and executes an exchange process of feeders 25 in mounting device 15 as an operation target. When the manufacturing of current board S ends, it is determined whether there is next production of board S, and when there is next production, loader 18 is caused to execute the setup change process. Loader 18 executes a process of installing each feeder 25 at the installation position of next production job 65.

Next, the mounting process by manual machine 15b will be described. The mounting process of manual machine 15b is executed in parallel with the mounting process of automatic machine 15a. A detailed description of the same processing as that in automatic machine 15a is omitted, assuming that the same processing is performed. First, operator W executes the setup change operation of installing each feeder 25 at the installation position set in production job 65. When the production can be started, operator W inputs and gives instruction to start the production to mounting system 10. When the mounting process is started, CPU 21 of manual machine 15b acquires production job 65 of the product to be manufactured this time from management device 60. Next, based on production job 65, CPU 21 executes processing of causing board process section 22 to load and fix board S, mounting head 32 to pick up component P from feeder 25 installed on component supply section 24, and putting component P on board S. When the disposition of component P on board S ends, CPU 21 discharges board S to board process section 22, and repeatedly executes the process described above. During the mounting process, CPU 21 manages the number of consumed components in each feeder 25, and when the remaining number of components is equal to or lower than a predetermined warning value, CPU 21 displays the information on operation panel 36. Operator W exchanges the supply members (feeders 25, the trays, and the like) that are out of components based on the display of operation panel 36. When the manufacturing of current board S ends, it is determined whether there is next production of board S, and when there is next production and there is the setup change operation, the contents of the setup change operation are displayed on operation panel 36. When there is the setup change operation, operator W executes the operation. In this way, in mounting system 10 including automatic machine 15a and manual machine 15b, loader 18 and operator W share the operation, exchange the supply members, and execute production plan information 64.

Here, a correspondence relationship between the elements of the present embodiment and the elements of the present disclosure will be clarified. Mounting system 10 of the present embodiment corresponds to a mounting system, mounting device 15 corresponds to a mounting device, automatic machine 15a corresponds to an automatic machine, manual machine 15b corresponds to a manual machine, loader 18 corresponds to a movable work device, and management device 60 corresponds to a management device. Mounting control section 20 corresponds to a mounting control section, component supply section 24 corresponds to a supply section, board S corresponds to a process target object, feeders 25 or the trays correspond to supply members, mounting section 30 corresponds to a mounting section, management control section 61 corresponds to a control section, production job 65 corresponds to a production job, and production plan information 64 corresponds to production plan information.

In management device 60 described above, in manual machine 15b of mounting device 15 in which the supply members, such as feeders 25, are manually exchanged, it is possible to further reduce the frequency of the setup change when the production of boards S as various process target objects is switched, by mainly setting the common setup. Further, in management device 60, in automatic machine 15a that is mounting device 15 in which the supply members are automatically exchanged, it is possible to set each of production jobs 65 in which the mounting process can be executed at a higher speed, by mainly setting the individual setup. Accordingly, in management device 60, it is possible to create production plan information 64 in consideration of the circumstances of automatic machine 15a and manual machine 15b, and it is possible to achieve higher efficiency in the production of board S.

In addition, since management control section 61 distributes the supply members to manual machine 15b so that the number of the supply members to be installed on manual machine 15b is reduced, it is possible to reduce the frequency with which operator W manually exchanges the supply members, and it is possible to further reduce the operation amount of operator W. In addition, in management device 60, it is possible to further suppress a production delay caused by an operation delay of operator W. Further, management control section 61 distributes, to manual machine 15b, the supply members capable of being handled only by manual machine 15b and sets the common setup in which the commonality of the installation positions of the supply members is further achieved. In management device 60, the mounting process of component P can be more reliably executed. Furthermore, mounting system 10 includes multiple automatic machines 15a, and management control section 61 distributes, to each automatic machine 15a, the supply members so that the process time required for each of automatic machines 15a is shorter. In management device 60, the production efficiency can be further improved by further shortening the process time. Mounting system 10 includes multiple automatic machines 15a, and management control section 61 distributes, to each automatic machine 15a, the supply members so that uniformity of the process times required for each of automatic machines 15a is achieved. In management device 60, the production efficiency can be further improved by further suppressing waiting for the process between the respective mounting devices. In addition, mounting system 10 may include multiple automatic machines 15a, and management control section 61 may distribute, to the manual machine, any one or more of the supply members distributed to the automatic machine side when the process time of automatic machine 15a is outside the predetermined allowable range. In this management device, by distributing the supply members to the manual machine side, more efficient production can be executed.

Management control section 61 distributes, to the manual machine 15b side, the supply members satisfying a distribution condition including one or more of the supply member holding component P having a higher degree of commonality based on common use in the production of the multiple types of boards S, the supply member holding component P used in fewer numbers than the standard component, and the supply member holding component P larger than the standard component. In management device 60, by distributing the supply members satisfying the distribution condition to the manual machine 15b side, more efficient production can be executed.

It is obvious that the present disclosure is not limited to the embodiment described above, and can be implemented in various modes as long as the modes belong to the technical scope of the present invention.

For example, in the embodiment described above, management device 60 distributes the supply members to be installed on manual machine 15b so that the number of the supply members to be installed on manual machine 15b is smaller, but the configuration is not limited to this. For example, management control section 61 may distribute the supply members to automatic machine 15a and manual machine 15b so that the uniformity of the process times required for automatic machine 15a and manual machine 15b is achieved. In management device 60, since the supply members are distributed so that the process times are uniformed, it is possible to execute smooth production between the respective devices. Since the operation amount of operator W can be reduced, it is more preferable that the number of the supply members to be installed on manual machine 15b is smaller.

In the embodiment described above, the supply member capable of being handled only by manual machine 15b is first distributed to manual machine 15b, but the supply member that can be handled by automatic machine 15a may also be distributed to manual machine 15b. It is more preferable that the supply members distributed to manual machine 15b are easy to be the common setup.

Further, in the embodiment described above, in the shortest mode, management control section 61 distributes the supply members to respective automatic machines 15a so that the process times required for respective automatic machines 15a are shorter, but the configuration is not limited to this. In mounting system 10, for example, it is possible to efficiently continue the mounting process even when the process time per unit process amount in each automatic machine 15a is not the shortest as in the optimum mode described above. Further, in the embodiment described above, in the shortest mode, the supply members are distributed to respective automatic machines 15a so that the uniformity of the process times required for respective automatic machines 15a is achieved, but the configuration is not limited to this. In mounting system 10, for example, it is possible to efficiently continue the mounting process even when the process time per unit process amount in each automatic machine 15a is not uniform as in the optimum mode described above.

In the embodiment described above, when the process time of automatic machine 15a is out of the predetermined allowable range, any one or more of the supply members distributed to automatic machine 15a are distributed to the manual machine 15b side, but the configuration is not limited to this. For example, management control section 61 may omit the processing of determining whether the process time is outside the predetermined allowable range. In this case, management control section 61 may set a distribution amount to manual machine 15b so that a distribution amount of automatic machine 15a is not excessive in accordance with, for example, the number of components or the number of feeders 25.

In the embodiment described above, the distribution condition is the degree of commonality, the used number with respect to the standard component, the size with respect to the standard component, and the like, but the configuration is not particularly limited to these as long as the condition is a condition suitable for the distribution to manual machine 15b, and one or more of conditions may be omitted, or a different condition may be further added.

Although not particularly described in the embodiment described above, the installation positions of the supply members may be changed in the device before the supply members are redistributed to another device, the process time may be obtained, and the process time may be saved when the process time is shorter than before the installation position is changed. In this way, the best installation position can be obtained without redistributing the supply members.

In the embodiment described above, mounting system 10 includes, in addition to mounting device 15, printing device 11, printing inspection device 12, storage device 13, storage PC 13a, mounting inspection device 16, conveyance device 17, loader 18, and reflow device 19, but the configuration is not particularly limited to this, and one or more of the devices described above may be omitted, or a device other than the devices described above may be added.

In the embodiment described above, the present disclosure is applied to the form of mounting system 10, but the present disclosure may be management device 60 or a production method.

Here, the management device, the mounting system, and the production method of the present disclosure may be configured as follows. For example, a mounting system of the present disclosure is a mounting system including a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section, and multiple mounting devices including one or more automatic machines in which the supply members are automatically exchangeable by the movable work device, and one or more manual machines in which the supply members are manually exchanged, in which the mounting device is configured to execute the mounting process by using a production job for each of multiple types of the process target objects included in production plan information set by distributing the supply members to be installed on the automatic machine with a tendency that an individual setup for installing the supply members at individual positions is mainly set in each production of the multiple types of the process target objects to the automatic machine, and distributing the supply members to be installed on the manual machine with a tendency that a common setup for installing the supply members holding a common component at a common position is mainly set in the production of the multiple types of the process target objects to the manual machine.

In the mounting system, as in the management device described above, it is possible to further reduce the frequency of the setup change when the production of various process target objects is switched, by mainly setting the common setup in the manual machine, and it is possible to execute the mounting process at a higher speed, by mainly setting the individual setup in the automatic machine. Accordingly, in the mounting system, it is possible to execute the production plan information in consideration of the circumstances of the automatic machine and the manual machine, and it is possible to achieve higher efficiency in the production of the process target object. In the mounting system, various configurations of the management device described above may be employed, or processing for achieving each function of the management device described above may be added.

A production method of the present disclosure is a production method for use in a mounting system including a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section, one or more automatic machines that are the mounting devices in which the supply members are automatically exchangeable by the movable work device, and one or more manual machines that are the mounting devices in which the supply members are manually exchanged, the production method including executing the mounting process by using production plan information including a production job for each of multiple types of the process target objects in which the supply members to be installed on the automatic machine with a tendency that an individual setup for installing the supply members at individual positions is mainly set in each production of the multiple types of the process target objects are distributed to the automatic machine, and the supply members to be installed on the manual machine with a tendency that a common setup for installing the supply members holding a common component at a common position is mainly set in the production of the multiple types of the process target objects are distributed to the manual machine.

In the production method, similarly to the management device described above, it is possible to further reduce the frequency of the setup change when the production of various process target objects is switched, by mainly setting the common setup in the manual machine, and it is possible to execute the mounting process at a higher speed, by mainly setting the individual setup in the automatic machine. Accordingly, in the mounting system, it is possible to execute the production plan information in consideration of the circumstances of the automatic machine and the manual machine, and it is possible to achieve higher efficiency in the production of the process target object. In the production method, various configurations of the management device described above may be employed, or steps for achieving each function of the management device described above may be added.

### INDUSTRIAL APPLICABILITY

The present disclosure is applicable to the technical field of a device that picks up and mounts components.

### REFERENCE SIGNS LIST

10: mounting system, 11: printing device, 12: printing inspection device, 13: feeder storage section, 13a: storage PC, 14: automatic conveyance vehicle, 15: mounting device, 15a: automatic machine, 15b: manual machine, 16: mounting inspection device, 17: conveyance device, 18: loader, 19: reflow device, 20: mounting control section, 21: CPU, 22: board process section, 23: support member, 24: component supply section, 25: feeder, 26: mounting installation section, 27: buffer installation section, 28: tray unit, 29: X-axis rail, 30: mounting section, 31: head moving section, 32: mounting head, 33: nozzle, 34: imaging section, 35: nozzle station, 36: operation panel, 37: communication section, 38: slot, 39: connection section, 50: movement control section, 51: CPU, 52: storage section, 53: accommodation section, 54: exchange section, 55: moving section, 58: communication section, 60: management device, 61: management control section, 62: CPU, 63: storage section, 64, 64B: production plan information, 65, 65B: production job, 68: communication section, P: component, S: board, W: operator

1. A management device for use in a mounting system including a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section, one or more automatic machines that are the mounting devices in which the supply members are automatically exchangeable by the movable work device, and one or more manual machines that are the mounting devices in which the supply members are manually exchanged, the management device comprising:
a control section configured to distribute, to the automatic machine, the supply members to be installed on the automatic machine with a tendency that an individual setup for installing the supply members at individual positions is mainly set in each production of multiple types of the process target objects, distribute, to the manual machine, the supply members to be installed on the manual machine with a tendency that a common setup for installing the supply members holding a common component at a common position is mainly set in the production of the multiple types of the process target objects, and create production plan information including a production job for each of the multiple types of the process target objects.

2. The management device according to claim 1,
wherein the control section is configured to distribute the supply members to be installed on the manual machine so that a fewer number of the supply members are installed on the manual machine.

3. The management device according to claim 1,
wherein the control section is configured to distribute, to the manual machine, the supply members capable of being handled only by the manual machine and set the common setup in which commonality of installation positions of the supply members is further achieved.

4. The management device according to claim 1,
wherein the mounting system includes the multiple automatic machines, and
the control section is configured to distribute, to each automatic machine, the supply members so that a process time required for each of the automatic machines is shorter.

5. The management device according to claim 1,
wherein the mounting system includes the multiple automatic machines, and
the control section is configured to distribute, to each automatic machine, the supply members so that uniformity of process times required for each of the automatic machines is achieved.

6. The management device according to claim 1,
wherein the mounting system includes the multiple automatic machines, and
the control section is configured to distribute, to the manual machine, any one or more of the supply members distributed to the automatic machine side when a process time of the automatic machine is outside a predetermined allowable range.

7. The management device according to claim 1,
wherein the control section is configured to distribute, to the manual machine side, the supply members satisfying a distribution condition including one or more of the supply member holding the component having a higher degree of commonality based on common use in the production of the multiple types of the process target objects, the supply member holding the component used in fewer numbers than a standard component, and the supply member holding the component larger than the standard component.

8. The management device according to claim 1,
wherein the control section is configured to distribute, to the automatic machine and the manual machine, the supply members so that uniformity of process times required for the automatic machine and the manual machine is achieved.

9. The management device according to claim 1,
wherein the mounting system includes a mounting related device including one or more of a printing device configured to form viscous fluid on the process target object, an inspection device configured to inspect the process target object, a conveyance device configured to convey the process target object, and a reflow device configured to reflow the process target object for which the mounting process is subjected, and
the control section is configured to distribute, to the automatic machine and the manual machine, the supply members to be within a range of a reference process time in the mounting related device.

10. A mounting system comprising:
a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section; and
multiple mounting devices including one or more automatic machines in which the supply members are automatically exchangeable by the movable work device, and one or more manual machines in which the supply members are manually exchanged,
wherein the mounting device is configured to execute the mounting process by using a production job for each of multiple types of the process target objects included in production plan information set by distributing the supply members to be installed on the automatic machine with a tendency that an individual setup for installing the supply members at individual positions is mainly set in each production of the multiple types of the process target objects to the automatic machine, and distributing the supply members to be installed on the manual machine with a tendency that a common setup for installing the supply members holding a common component at a common position is mainly set in the production of the multiple types of the process target objects to the manual machine.

11. A production method for use in a mounting system including a movable work device configured to automatically exchange supply members of a mounting device including a mounting section configured to execute a mounting process of components on a process target object, a supply section configured to install the supply members holding the components and supply the components, and a mounting control section configured to cause the mounting section to pick up the components from the supply section, one or more automatic machines that are the mounting devices in which the supply members are automatically exchangeable by the movable work device, and one or more manual machines that are the mounting devices in which the supply members are manually exchanged, the production method comprising:
executing the mounting process by using production plan information including a production job for each of multiple types of the process target objects in which the supply members to be installed on the automatic machine with a tendency that an individual setup for installing the supply members at individual positions is mainly set in each production of the multiple types of the process target objects are distributed to the automatic machine, and the supply members to be installed on the manual machine with a tendency that a common setup for installing the supply members holding a common component at a common position is mainly set in the production of the multiple types of the process target objects are distributed to the manual machine.
